(19) United States
(12) Patent Application Publication
(10) Pub. No.: US 2005/0016764 A1
(43) Pub. Date: Jan. 27, 2005

(54) Wiring substrate for intermediate connection and multi-layered wiring board and their production

(76) Inventors: Fumio Echigo, Osaka-shi (JP); Kumiko Hirayama, Moriguchi-shi (JP); Yoji Ueda, Osaka-shi (JP); Yasuhiro Nakatani, Kawachinagano-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/897,087

(22) Filed: Jul. 23, 2004

(30) Foreign Application Priority Data
Jul. 25, 2003 (JP) P2003-279719

(51) Int. Cl. H05K 1/11; H05K 3/36

(52) U.S. Cl. 174/256; 174/258; 29/830; 174/264

(57) ABSTRACT

There is provided a wiring substrate for intermediate connection comprising: (1) a wiring board having a plurality of wiring layers which are connected through a via hole conductor(s) with each other; and (2) a prepreg sheet having a via hole conductor(s) at a predetermined position(s) which sheet is disposed on at least one side of the wiring board.

### CROSS REFERENCE TO RELATED APPLICATION

The present application claims priority under 35 U.S.C. § 119 to Japanese Patent Application No. 2003-279719 (fined on Jul. 25, 2003, entitled “WIRING SUBSTRATE FOR INTERMEDIATE CONNECTION AND MULTI-LAYERED WIRING BOARD AND THEIR PRODUCTION”. The contents of that application are incorporated herein by reference in their entirety.

### BACKGROUND OF THE INVENTION

1. Field of the Invention

The present invention relates to a wiring substrate for intermediate connection which is used for the production of wiring boards for a variety of electronic devices, particularly compact and light electronic devices having high performances, and especially mobile electronic devices. Also the present invention relates to multi-layered wiring boards (or multi-layer wiring boards) produced by using the wiring substrate for intermediate connection and production processes of the wiring substrate for intermediate connection and also the multi-layered wiring board.

2. Description of the Related Art

In these years, increasing desires as to electronic devices to be thinner and lighter and also to be more highly efficient have made various electronic parts which form the electronic devices compacter and thinner. Wiring boards on which the electronic parts are mounted are also desired to be thinner while they allow higher density multi-layered wiring.

Particularly recently, with rapid developments of mounting technologies, a multi-layered wiring board is highly desired with a lower cost which allows direct and high density mounting of bare chips of semiconductor devices such as an LSI onto a printed circuit board. It is important that such a multi-layered wiring board has a high reliability of electrical connections between plural wiring layers (or wiring patterns) formed with a small wiring pitch as well as good high frequency properties.

For this reason, developments of a wiring board has been conducted in various fields which has a via hole structure or an inner via hole structure (hereinafter, which is also referred to as “IVH”) which allows connection between a semiconductor chip and an electronic part over a shortest distance.

As one example of such a wiring board, there is a resin made multi-layered wiring board having the IVH structure as to all wiring layers thereof. With such wiring board, the improvement in the electrical connection reliability is achieved by filling with an electrically conductive material (for example, a conductive paste) inner via holes formed through a thermoset resin substrate which is in a prepreg condition followed by pressing when the resin is heated for curing wherein, any IVH can be formed between wirings or just below lands for electronic parts, so that the reduction of a wiring board size, the high density mounting and so on become possible. Such resin made multi-layered wiring board having the IVH structures throughout wiring layers thereof allows only required connection between wiring layers and provides ease upon mounting. For example, see Japanese Patent Kokai Publication Nos. 47991/1988 and 268345/1994.

A production process for a multi-layered wiring board is disclosed wherein a plurality of wiring substrates are stacked while being aligned, each of which substrate is produced by pressing a wiring layer transfer sheet and an insulation layer in a semi-cured condition together so as to transfer a wiring layer to the insulation layer, followed by heating the substrates so as to completely cure the insulation layers, whereby an integrated laminate is obtained. For example, see Japanese Patent Kokai Publication No. 27959/1998, and especially FIG. 1 thereof.

A further process is proposed in which plural single sided wiring boards each having through holes and an adhesive layer applied on a side without a wiring layer are stacked together and aligned with each other to form a core member, and an outermost conductor layer is placed on each outermost side of the core member, followed by pressing all together to form a laminate and by finally etching the outermost conductor layer to form a wiring layer. For example, see Japanese Patent Kokai Publication Nos. 320167/2001, and especially FIGS. 1 and 2 thereof.

A process for producing a wiring board having an IVH structure disclosed in Japanese Patent Kokai Publication No. 268345/1994 will be explained hereinafter with reference to the accompanied drawings.

FIGS. 9(a) to 9(g) each schematically shows in a cross-sectional view a step of a conventional production process of the wiring board having the IVH structure. As shown in FIG. 9(a), a prepreg sheet 2 is provided on each surface of which a release film 1 is applied which comprises a polymer film like a PET film having a thickness of about 20 micrometers on which one surface a release layer is formed. As shown in FIG. 9(b), predetermined through holes 3 are formed through the prepreg sheet 2 using energy beam like laser. The through holes are filled with an electrically conductive paste comprising predominantly copper powder using a printing technology, followed by removing the release films 1 from the prepreg sheet 2 so as to form an intermediate connector 5a having via hole conductors 4 as shown in FIG. 9(c).

Next, a metal foil 6 such as a copper foil is laminated on each side of the intermediate connector 5a, followed by heating and pressing as they are, so that the prepreg sheet 2 and the metal foils 6 are bonded together while compressed and simultaneously electrically connected through the via hole conductors 4 as shown in FIG. 9(d). Upon such heating and pressing, an epoxy resin which forms the prepreg sheet and the via hole conductors are cured. Thereafter, each of the metal foils 6 is selectively etched by the conventional etching photolithography so that a double-sided wiring board 8 having predetermined wiring layers 7 is obtained as shown in FIG. 9(e).

Then, a predetermined intermediate connector 5b or 5c which is similar to the intermediate connector as shown in FIG. 9(f) is stacked on each side of the above obtained double-sided wiring board 8 as a core member, and a metal foil 9 such as a copper foil is further stacked on each of the intermediate connector followed by heating and pressing all together. Thereafter, each of the metal foils 9 is selectively etched to form a predetermined wiring layer 10 so that a multi-layered wiring board 9 having four wiring layers is obtained as shown in FIG. 9(g).

When a multi-layered wiring board having more than four wiring layers, the multi-layered wiring board as shown in FIG. 9(g) is used as a core member again, and an intermediate connector as well as a metal foil is stacked on one or each side of the core member, and the heating and pressing step as shown in FIG. 9(f) is repeated.

It is likely that with the conventional production process of the multi-layered wiring board, and in particular a successively stacking process as described in Japanese Patent Kokai Publication Nos. 47991/1988 and 268345/1994, the number of the stacking steps of the core member and the intermediate connector is increased when the number of the wiring layers is increased, so that the process becomes complicated and thus defective occurrence is increased whereby a product yield gets worse.

Also it is likely that in the all together laminating process as described in Patent Kokai Publication Nos. 27959/1998 and 320167/2001 wherein a number of prepreg sheets are laminated, it is difficult to prepare a thin insulation layer for the prepreg sheet, and alignment accuracy upon sheet stacking becomes worse due to the large number of the sheets.

### SUMMARY OF THE INVENTION

In order to solve or at least alleviate the above problems, the present invention provides a wiring substrate for intermediate connection which is used for the production of and which constitutes a multi-layered wiring board, and such wiring substrate comprises the following members:
(1) a wiring board including plural wiring layers which are connected with each other through a via hole conductor(s); and
(2) a prepreg sheet which is placed on at least one side of the wiring board and which contains a via hole conductor(s) at a predetermined position(s).

In the connection substrate for intermediate connection according to the present invention, said wiring board comprises at least one insulation layer and wiring layers which sandwich the insulation layer. The wiring layers are electrically connected with each other as predetermined through the via hole conductors (i.e. through an electrically conductive material which is filled in via holes). Said wiring board as above may be a double-sided wiring board (i.e. a wiring board which comprises a single insulation layer having a wiring layer on each side thereof) or a multi-layered wiring board (i.e. a wiring board which comprises at least two insulation layers having at least three wiring layers, any two adjacent wiring layers of which sandwich an insulation layer). In the case of the multi-layered wiring board, said wiring board may be a wiring board which is produced by using the wiring substrate(s) for intermediate connection according to the present invention which will be hereinafter described in detail.

The connection substrate for intermediate connection according to the present invention can be used for producing a predetermined wiring board by heating and pressing the connection substrate for intermediate connection with at least one other member (for example, other wiring board, a metal foil, other kind of a wiring substrate for intermediate connection (or an intermediate connector) or the like) while stacking them so as to integrate them together (i.e. thermally laminating for bonding them). Hereinafter, the wiring board which is produced by using the wiring substrate(s) for intermediate connection of the present invention is also referred to as a “final product wiring board” so as to distinguish it from said wiring board which forms the wiring substrate for intermediate connection according to the present invention. That is, the connection substrate for intermediate connection according to the present invention is a material as an intermediate product which is used with the above mentioned other member for the production of the final product wiring board, and in this sense, the term “intermediate” is used in the “wiring substrate for intermediate connection”.

Upon heating and pressing as described above, said wiring board which forms the wiring board for intermediate connection is in a completed condition as a wiring board, and therefore its size does not substantially change, that is, it is dimensionally stable. Generally, said wiring board is made of an insulation layer which comprises a thermoset resin. Said wiring board which forms the wiring board for intermediate connection of the present invention contains a thermoset resin which is in a substantially completely cured condition, so that its size is stable. In other embodiment, said wiring board is made of an insulation layer which comprises a thermoplastic resin. In this case, such thermoplastic resin has such a higher softening temperature or a melting temperature than a heating temperature that substantially no size change of said wiring board is caused upon heating and pressing. The via hole conductor(s) which said wiring board has contains in addition to the electrically conductive material, a thermoset resin, which is also in the completely cured condition as in the insulation layer, so that it is also dimensionally stable.

In the wiring substrate for intermediate connection according to the present invention, the prepreg sheet comprises a thermoset resin (which forms an insulation layer) in its semi-cured or uncured condition (i.e. in the so-called prepreg condition) and the via hole conductor(s). Via hole(s) is formed at a given position(s) such that the via hole conductor(s) electrically connect(s) the wiring layers of said wiring board as predetermined. In the via hole(s), an electrically conductive material such as an electrically conductive paste is filled in its semi-cured or uncured condition. The conductive material is cured to finally provide the via hole conductor(s), and in the wiring substrate for intermediate connection, it is in its semi-cured or uncured condition, i.e. in the so-called prepreg condition.

The thickness of the prepreg sheet is not particularly limited, and it is usually not greater than 100 micrometers, and preferably not greater than 50 micrometers. With the prepreg sheet has such a thickness, its handling becomes easier when it is in the form of the wiring substrate for intermediate connection compared with when it is handled alone. The prepreg sheet has a thickness not smaller than 10 micrometers and preferably not smaller than 25 micrometers. Also, the thickness of the insulation layer of said wiring board is not particularly limited, and when a double-sided wiring board is used, the thickness of the insulation layer has a thickness usually not greater than 100 micrometers, and preferably not greater than 50 micrometers, and usually not smaller than 10 micrometers, and preferably not smaller than 25 micrometers. When such said wiring board of which insulation thickness is in the above ranges is used, handling of the prepreg sheet becomes easier when it is in the form of the wiring substrate for intermediate connection compared with when the prepreg sheet is handled alone.

It is noted that the via hole may pass completely through the prepreg sheet or it may be a blind hole (i.e. not completely passing through, and there remains a thin layer of a prepreg material between the bottom of the blind hole and its adjacent wiring layer). The wiring substrate for intermediate connection according to the present invention is heated and pressed together with other member (for example, other wiring board, a metal foil, other kind of a wiring substrate for intermediate connection or the like) as described later so as to laminate them together. When such a thin layer remains, it substantially disappears upon heating and pressing, so that the conductive material in the via hole is in electrically contact with the wiring layer which is positioned adjacent to the thin layer.

The present invention provides a process of producing the wiring substrate for intermediate connection as described above, which process comprises the steps of stacking on and bonding to said wiring board as described above the prepreg sheet as described above which includes no via hole, then forming the via hole(s), and filling the via hole(s) with the conductive material (for example, the conductive paste). The formation of the via hole(s) is carried out such that the conductive material filled therein electrically connects the wiring layer as predetermined on a surface of the wiring board on which surface the prepreg sheet is placed. It is noted that upon the formation of the via hole(s), the prepreg sheet which is bonded to said wiring board may have a release sheet thereon, and in such case, the via hole(s) is formed through also the release sheet.

Bonding of the prepreg sheet and said wiring layer which are stacked may be carried out in any appropriate known manner. For example, when the prepreg sheet develops adhesiveness or tackiness upon being heated, the prepreg sheet may be heated for the purpose of bonding provided that the prepreg condition of the prepreg sheet is kept. In other embodiment, the prepreg sheet may have an adhesive layer on at least a surface which is adjacent to said wiring board. As such an adhesive layer, an appropriate thermoset resin or thermoplastic resin may be used. Resins which may be used are for example an epoxy resin, a polyimide resin and a polyamide resin. The adhesive layer may have the adhesiveness at room temperature or may develop the adhesiveness when heated.

In other words, the process for the production of the wiring board for intermediate connection according to the present invention comprises the steps of:
(a) stacking on at least one surface of said wiring board as described above, a prepreg sheet without a via hole on which a release film is pasted such that the prepreg sheet is adjacent to said wiring board, and bonding them together;
(b) forming a via hole(s) completely through the prepreg sheet or not completely through the prepreg sheet from a release film side of the prepreg sheet;
(c) forming a via hole conductor(s) by filling a conductive paste in the via hole(s); and
(d) removing the release film if necessary.

Also, the present invention provides a multi-layered wiring board as a final product wiring board formed by stacking plural predetermined wiring substrates for intermediate connection according to the present invention together so as to laminate them integrally. It is noted that the predetermined wiring substrates for intermediate connection means such wiring substrates for the intermediate connection that the wiring layers and the via hole conductors of each wiring substrate are electrically connected as predetermined when the plurality of the wiring substrates for intermediate connection are stacked and bonded together. With the such multi-layered wiring board, since a required number of the predetermined wiring substrates for intermediate connection can be heated and pressed together to be integrally laminated, alignment accuracy upon such laminating becomes very good. It is noted that an already completed wiring board may be placed between the wiring substrates for intermediate connection if necessary.

Further, the present invention provides a process for the production of the multi-layered wiring board as described above, wherein a plurality of the predetermined wiring substrates for intermediate connection according to the present invention are stacked and aligned, and then those substrates are laminated together and bonded integrally such that the wiring layers of those substrates are connected as predetermined through the via hole conductors. If necessary, other wiring board (such as a double-sided wiring board, a multi-layered wiring board or the like) may be placed as an outermost member or inserted between two adjacent wiring substrates for intermediate connection.

It is noted that in the above process for the production of the multi-layered wiring board and also in the other production processes which will be described below, bonding can be achieved by the adhesiveness which the prepreg sheet, in particular the thermoset resin therein develops when it is heated. Such heating is preferably at such a temperature and for such a period that curing of the thermoset resin of the prepreg sheet and also the thermoset resin of the via hole conductor are substantially completed.

In one embodiment of the process for the production of the multi-layered wiring board, a double-sided wiring board or multi-layered wiring board which has an insulation layers of a glass-epoxy resin is used as a core wiring board, on each side of which one or more wiring substrates for intermediate connection according to the present invention is stacked, followed by heating and pressing so as to laminate and bond them together, whereby the outermost wiring layers of the core wiring board and the wiring layers of the wiring substrates for intermediate connection are connected through the via hole conductors of the wiring substrates for intermediate connection. Thereby, it becomes possible to form a multi-layered wiring board which has more wiring layers by using the conventional double-sided wiring board or multi-layered wiring board. Such core wiring board may be a flexible wiring board, which may be converted to a flexible multi-layered wiring board having more wiring layers. Such flexible multi-layered wiring board may be installed while being folded in a compact mobile electronic device such as a mobile phone.

In the production process of the multi-layered wiring board according to the present invention, when a plurality of the wiring substrates for intermediate connection and other required wiring board(s) are stacked, a wiring layer transfer sheet which comprises a predetermined wiring layer or a metal foil which is to be a predetermined wiring layer may be placed as one or each outermost layer of thus stacked substrates and other wiring board such that it is in contact with the prepreg sheet of the wiring substrate for intermediate connection, and then all of them are laminated together. When the wiring layer transfer sheet is used, the outermost wiring layer is buried in the insulation layer by heating and pressing, so that a multi-layered wiring board is obtained of which surface having the wiring layer is smooth.

As seen from the above description, since the wiring substrate for intermediate connection of the present invention comprises said wiring board which is dimensionally stable, it can be handled with ease when it is laminated with other member with high alignment accuracy. As a result, a final product wiring board as a super multi-layered wiring board can be produced which has many fine wiring layers which are connected by the via hole conductors.

The wiring substrate for intermediate connection according to the present invention comprises, as a unit wiring board for the production of a multi-layered wiring board, said wiring board having a plurality of the wiring layers which are connected with the via hole conductors, at least one surface of which wiring board the insulation layer made of the prepreg sheet having the via hole conductor(s) at a predetermined position(s) is arranged. Even if the wiring substrate for intermediate connection is made thinner, because it comprises as a part thereof said wiring board completely cured With a highly accuracy of its dimension, the wiring substrate for intermediate connection is superior to be handled in the lamination step, so that extremely high accurate alignment and/or positioning can be achieved. As a result, a super multi-layered wiring board comprising very fine wiring layers can be realized.

It is noted that in the wiring substrate for intermediate connection according to the preset invention, a double-sided wiring board having a wiring layer on each side thereof can be used, but a multi-layered wiring board comprising a number of wiring layers which is produced as a final product wiring board by using the wiring board for intermediate connection according to the present invention can be used as said wiring board. In this case, since the insulation layer of the final product wiring board used as said wiring board already has a number of precisely formed wiring layers therein, further higher density wiring can be accomplished.

### BRIEF DESCRIPTION OF DRAWINGS

FIGS. 1(a) and 1(b) each shows in a schematic cross sectional view, a wiring substrate for intermediate connection of embodiment 1 according to the present invention;

FIGS. 2(a) to 2(e) each shows in a schematic cross sectional view, a step for the production process of a wiring substrate for intermediate connection of embodiment 2 according to the present invention;

FIGS. 3(a) to 3(c) each shows in a schematic cross sectional view, a step for the production process of a multi-layered wiring board of embodiment 3 according to the present invention;

FIGS. 4(a) to 4(c) each shows in a schematic cross sectional view, a step for the production process of a multi-layered wiring board of embodiment 4 according to the present invention;

FIGS. 5(a) to 5(c) each shows in a schematic cross sectional view, a step for the production process of a multi-layered wiring board of embodiment 5 according to the present invention;

FIGS. 6(a) to 6(c) each shows in a schematic cross sectional view, a step for the production process of a multi-layered wiring board of embodiment 6 according to the present invention;

FIGS. 7(a) and 7(b) each shows in a schematic cross sectional view, a step for the production process of a multi-layered wiring board of embodiment 7 according to the present invention;

FIGS. 8(a) to 8(c) each shows in a schematic cross sectional view, a step for the production process of a multi-layered wiring board of embodiment 8 according to the present invention; and

FIGS. 9(a) to 9(g) each shows in a schematic cross sectional view, a step for the conventional production process of a multi-layered wiring board.

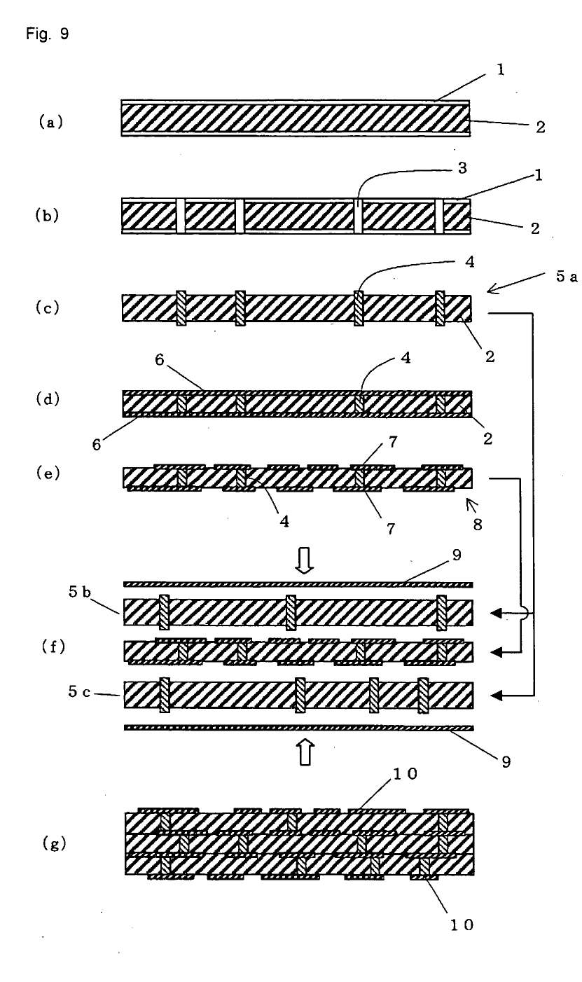

In the drawings, reference numbers denote the followings:
11 . . . insulation layer, 12a . . . first wiring layer, 12b . . . second wiring layer, 13a, 13b . . . via hole conductor, 14 . . . wiring board, 15 . . . prepreg sheet (insulation layer), 21 . . . insulation layer, 22a . . . first wiring layer, 22b . . . second wiring layer, 23a . . . via hole conductor, 24 . . . wiring board, 25 . . . prepreg sheet (insulation layer), 26 . . . release film, 27 . . . via hole, 28 . . . via hole conductor (electrically conductive paste), 29 . . . wiring substrate for intermediate connection, 31 . . . insulation layer, 32a . . . first wiring layer, 32b . . . second wiring layer, 33a . . . via hole conductor, 34 . . . wiring board, 35 . . . prepreg sheet (insulation layer), 36a-d . . . wiring substrate for intermediate connection, 37 . . . metal foil, 38 . . . wiring layer, 41 . . . metal foil, 42a-d . . . wiring substrate for intermediate connection, 43 . . . prepreg sheet, 44 . . . via hole conductor, 45 . . . metal foil, 46 . . . metal foil pasted connector, 47 . . . laminate, 48a, 48b . . . wiring layer, 49 . . . multi-layered wiring board, 51a-d . . . wiring substrate for intermediate connection, 54 . . . intermediate connector, 55a, 55b . . . carrier, 56a, 56b . . . wiring layer, 57, 58 . . . wiring layer transfer sheet, 59 . . . laminate, 61 . . . wiring substrate for intermediate connection, 62a, 62b . . . wiring substrate for intermediate connection, 63a, 63b . . . wiring substrate for intermediate connection, 64a, 64b . . . metal foil, 65 . . . laminate, 66a, 66b . . . outermost wiring layer, 71 . . . inside wiring layer, 72a, 72b . . . outermost wiring layer, 73 . . . through hole conductor, 74 . . . core wiring board, 75a, 75b . . . wiring substrate for intermediate connection, 76a, 76b . . . via hole conductor, 81 . . . core wiring board, 82a, 82b . . . wiring layer, 83 . . . insulation layer, 84, 85 . . . wiring substrate for intermediate connection, 86, 87 . . . wiring layer, 88, 89 . . . via hole conductor, 91 . . . core wiring board, 92-95 . . . wiring substrate for intermediate connection

### DETAILED DESCRIPTION OF THE INVENTION

The insulation layer of the wiring board as well as the prepreg sheet (wherein in the case of the prepreg, a material to form the insulation layer in the final product wiring board) in the wiring substrate for intermediate connection of the present invention may be formed from a woven or unwoven fabric of an organic fiber (for example, an aramid fiber) or inorganic fiber (for example, a glass fiber) which fabric is impregnated with at least one thermoset resin (for example, an epoxy resin, a phenol resin and a cyanate resin). It is noted that in said wiring board, curing of the thermoset resin is completed, while curing of the thermoset resin is not completed in the prepreg sheet, and the thermoset resin is preferably in the uncured or semi-cured condition. The insulation layer of said wiring board may be formed of a thermoplastic resin (for example, a polybutadiene resin, a polyimide resin, a polyamide resin, a polyphenylene sulfide resin and so on). These resins can improve heat resistance and mechanical strength of said wiring board. It is noted that as the prepreg sheet, a synthetic resin film may be used which is made of for example a polyethylene terephthalate, a polyester terephthalate, a polyimide or a polyphenylene sulfide onto which surface the above mentioned thermoset resin which is in the prepreg condition is applied as an adhesive.

In the wiring substrate for intermediate connection of the present invention, the via hole conductor includes particles of at least one an electrically conductive metal (for example, gold, silver, copper, palladium, tin and nickel) as an electrically conductive component and a thermoset resin, which leads to high connection reliability in a thinned multi-layered wiring board. For such via hole conductor, any known conductive paste can be used which is conventionally used for the production of a wiring board having via hole conductors. Similarly to the above described insulation layer, curing of the thermoset resin of the via hole conductor has been substantially completed in said wiring board, while not completed in the prepreg sheet and preferably in an uncured or semi-cured condition.

The wiring substrate for intermediate connection of the present invention which comprises the via hole conductor(s) can be produced by
placing on at least one side of said wiring board, the prepreg sheet (to which a release film is preferably stuck on the other side thereof which does not face to said wiring board), and joining them together;
irradiating the prepreg sheet with energy beam (such as carbon dioxide gas laser beam) (preferably from the above of the prepreg sheet) so as to form a completely through hole(s) or not completely through hole(s); and then
filling the hole(s) with the conductive paste comprising, as the conductive component, particles of a metal (such as gold, silver, copper, palladium, tin and nickel) using for example a screen printing technique.

In the case wherein the prepreg sheet has the release film, the wiring substrate for intermediate connection comprises the via hole conductor(s) which has a protruding part which extends from a surface the prepreg sheet by a thickness of the release film by removing the release film if necessary.

Embodiments of the present invention will be hereinafter explained with reference to the accompanying drawings.

Embodiment 1

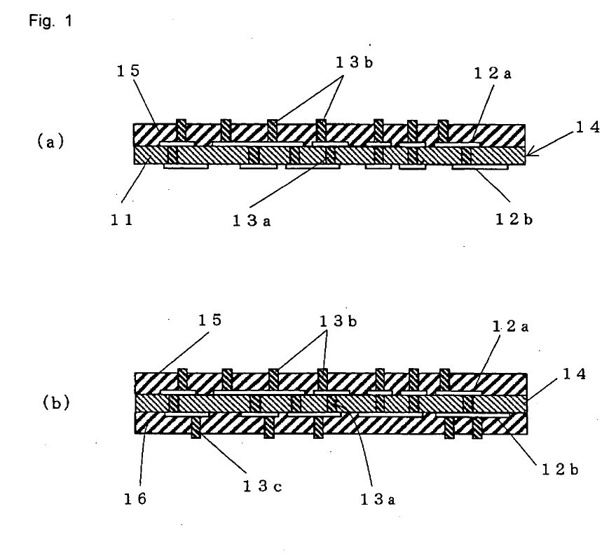

FIGS. 1(a) and 1(b) each schematically shows as embodiment 1 a wiring substrate for intermediate connection of the present invention. In FIG. 1(a), the wiring substrate for intermediate connection is configured such that a prepreg sheet 15 (having a thickness of for example less than 50 μm) which has via holes filled with a conductive paste 13b in a semi-cured condition is bonded to one surface (top surface in the shown embodiment) of a double-sided wiring board 14 which comprises an insulation layer 11 (having a thickness of for example less than 50 μm) having a first wiring layer 12a and a second wiring layer 12b on either side thereof respectively which are formed of metal foils (such as a copper foil) and which are connected as predetermined with via hole conductors (already cured) 13a containing copper powder as a dominant conductive component. Such bonding is carried out by thermo-compression at a temperature at which curing of the thermoset resin of the prepreg and the conductive paste does not complete, and preferably does not substantially proceed.

FIG. 1(a) shows as one example the embodiment wherein the prepreg sheet 15 bonded to one side of the double-sided wiring board 14, but it is possible as shown in FIG. 1(b) that onto the other side of the wiring board 14, a prepreg sheet 16 (having a thickness of for example less than 50 μm) is bonded which has via holes filled with conductive paste 13c to be via hole conductors. Further, in place of the double-sided wiring board 14, a multi-layered wiring board having plural wiring layers may be used which has one or more wiring layers inside of the wiring board.

The prepreg sheets 15 and 16 in the present invention may be formed by impregnating a fabric sheet such as an aramid fiber unwoven fabric with a thermoset resin such as an epoxy resin in a semi-cured condition. The other materials for the unwoven fabric includes an organic fiber of a polyimide, a poly-p-phenylene benzobisoxazole, an all aromatic polyester, a PTFE, a polyethersulfone, and a polyether imide as well as an inorganic fiber such as a glass fiber and an alumina fiber. Further, in place of the unwoven fabric, a woven fabric may be employed and in such case, the fabric comprises an organic fiber such as an aramid fiber and an all aromatic polyester fiber, or an inorganic fiber such as a glass fiber or an alumina fiber.

As the thermoset resin, a phenol resin or a cyanate resin may be used in addition to the epoxy resin, which also leads to the wiring substrate for intermediate connection having high heat-resistance.

The thermoset resin may comprise as an additional component an additive(s) so as to improve a necessary property. For example, it is desirable that it contains an inorganic filler of alumina, magnesium oxide, boron nitride, aluminum nitride, silicon oxide or the like for the improvement of electrical insulation and mechanical strength.

The prepreg sheet 15 formed of the unwoven or woven fabric is explained in the above, and other material may be used for forming the prepreg sheet. Such other material is a composite material which comprises a film of a synthetic resin (such as a p-aramid, a poly-p-phenylene benzobisoxazole, an all aromatic polyester, a polyether imide, a polyetherketone, a polyetheretherketone, a polyethylene terephthalate, a polytetrafluoroethylene, a polyethersulphon, a polyester terephthalate, a polyimide, and a polyphenylene sulfide) and the above mentioned thermoset resin as an adhesive in the prepreg condition which is applied onto the film.

Embodiment 2

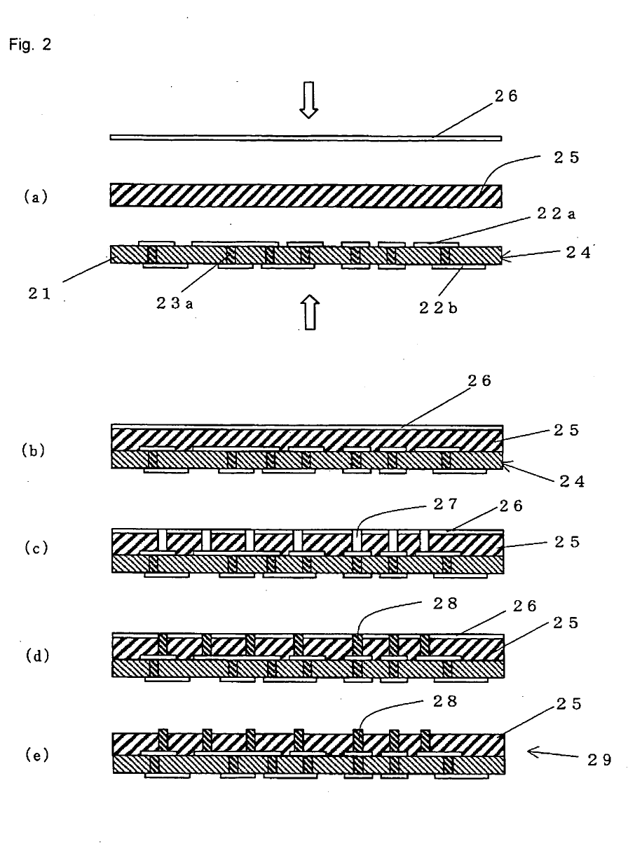

A production process of the wiring substrate for intermediate connection of the present invention is explained with reference to FIG. 2. FIGS. 2(a) to 2(e) each shows in a cross sectional view a step of the manufacturing process of the wiring substrate for intermediate connection of the present invention. As shown in FIG. 2(a), a prepreg sheet 25 (for example, a prepreg sheet in which a thermoset resin such as an epoxy resin is impregnated in the fibrous sheet of an aramid fiber unwoven fabric, and the resin is kept in the semi-cured condition (that is, in the B-stage condition)) is stacked on a double-sided wiring board 24 in which a first wiring layer 22a and a second wiring layer 22b installed on either side of the insulating layer 21 are connected through the via hole conductors 23a, and a release film 26 (for example, a release film made of a polyethylene terephthalate) having a thickness of about 20 micrometers is stacked on the prepreg sheet 25. Then, they are passed through between two heated rolls so that they pressurize and laminate them integrally as shown in the arrows at a temperature such that the impregnated resin does not completely cure, so that a bonded product is formed as shown in FIG. 2(b).

As shown in FIG. 2(c), completely through holes or not completely through holes 27 having a cross section of which maximum diameter is not greater than about 100 micrometers are formed by irradiating energy beam such as carbon dioxide gas laser to predetermined positions from the side of the release film 26. In the shown embodiment, the through holes completely pass through the prepreg sheet 25.

It is noted that the form of the hole 27 is not particularly limited and it may be a column or a truncated cone having cross sections of a larger diameter circle and a smaller diameter circle. In any case, a maximum diameter (or size) of the cross section of the hole is not larger than 200 micrometers and preferably not larger than 100 micrometers.

Next, as shown in FIG. 2(d), a conductive paste (in an uncured or semi-cured condition) comprising a conductive powder (such as copper powder) and an epoxy resin is filled in the holes 27 as the via hole conductors by the printing method so as to obtain the wiring substrate for intermediate connection according to the present invention. When necessary (for example, so as to use the wiring substrate for intermediate connection), as shown in FIG. 2(e), the release film 26 is peeled off so that the wiring substrate for intermediate connection 29 is formed in which the via hole conductors 28 each has a part which slightly protrudes above the top surface of the prepreg sheet 25.

It is noted that as the electrically conductive material of the conductive paste which forms the via hole conductor, power of, in addition to copper, gold, silver, palladium, tin, and nickel and an alloy of any combination thereof may be used so as to obtain good results.

In the embodiment shown in FIG. 2, the double-sided wiring board 24 has the via hole conductors. In place of such double-sided wiring board, it is possible to use a double-sided wiring board which is produced by the so-called built-up method wherein wiring layers on the both sides of the insulation layer are connected by plating or a multi-layered wiring board of which insulation layer has plural wiring layers.

As seen from the above explanation, the wiring substrate for intermediate connection of the present invention uses as a support the substantially rigid insulation layer (or insulation plate) of the wiring board which has been already completed, and is formed by laminating the prepreg sheet in the uncured or preferably semi-cured condition on at least one surface of such support. Such wiring substrate for intermediate connection has the via hole conductors in the uncured or semi-cured condition in the via holes of the prepreg sheet which conductors are located on predetermined lands of the wiring layer on said wiring board. As a result, when a plurality of the wiring substrate for intermediate connection each comprising predetermined wiring layers are stacked and aligned so as to produce a multi-layered wiring board, accuracies upon the alignment as to fine wiring width, fine wiring pitch and land formation are improved. Therefore, being thinner and having more wiring layers are achieved while having good connection reliability simultaneously through the wiring substrate for intermediate connection according to the present invention.

Embodiment 3

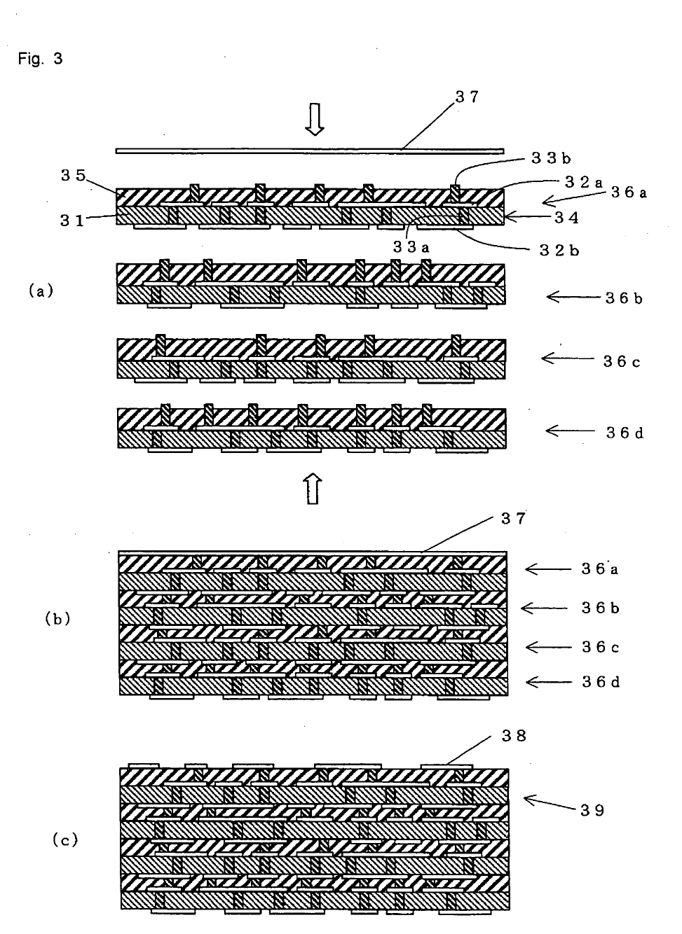

The multi-layered wiring board of the present invention and its production process of embodiment 3 are explained referring to FIG. 3. This embodiment produces the multi-layered wiring board with using the wiring substrate for intermediate connection which is described in the above embodiments 1 and 2.

FIGS. 3(a) to, 3(c) each shows a step for the production process of the multi-layered wiring board in the present embodiment. The wiring substrate for intermediate connection 36a as shown in FIG. 1(a) (which is formed by laminating a prepreg sheet 35 having via hole conductors 33b in the semi-cured condition onto one surface of a double-sided wiring board 34 having a first wiring layer 32a and a second wiring layer 32b on both sides of an insulation layer 31 which are connected with via hole conductors 33a is stacked together and aligned with similar wiring substrates for intermediate connection 36b, 36c and 36d which may be the same or different from each other such that the insulation layer 31 and the prepreg sheet 35 are located alternately as shown in FIG. 3(a).

A metal foil 37 such as a copper foil is placed on the wiring substrate for intermediate connection 36a and pressed as shown with the arrows while heating the prepreg sheets 35 and the via hole conductors 33b in the semi-cured condition so as to completely cure them so that a laminate is obtained as show in FIG. 3(b). Then, the metal foil 37 is selectively etched so as to form a predetermined outermost wiring layer 38, so that the multi-layered wiring board 39 is obtained.

As seen from the above, the present invention provides a process for the production of the multi-layered wiring board comprising the steps of:
stacking and aligning a plurality of the wiring substrates for intermediate connection 36a to 36d each having the predetermined wiring layers such that the prepreg sheet 33 and said wiring board 34 are arranged alternately;
placing a metal foil 37 on a top surface of the prepreg sheet of the top wiring substrate for intermediate connection of thus stacked wiring substrates for intermediate connection while aligning the foil with the stacked substrates;
heating and pressing the wiring substrates for intermediate connection and the metal foil together so as to laminate them integrally; and
selectively etching the metal foil to form the predetermined wiring layer 38.

Embodiment 4

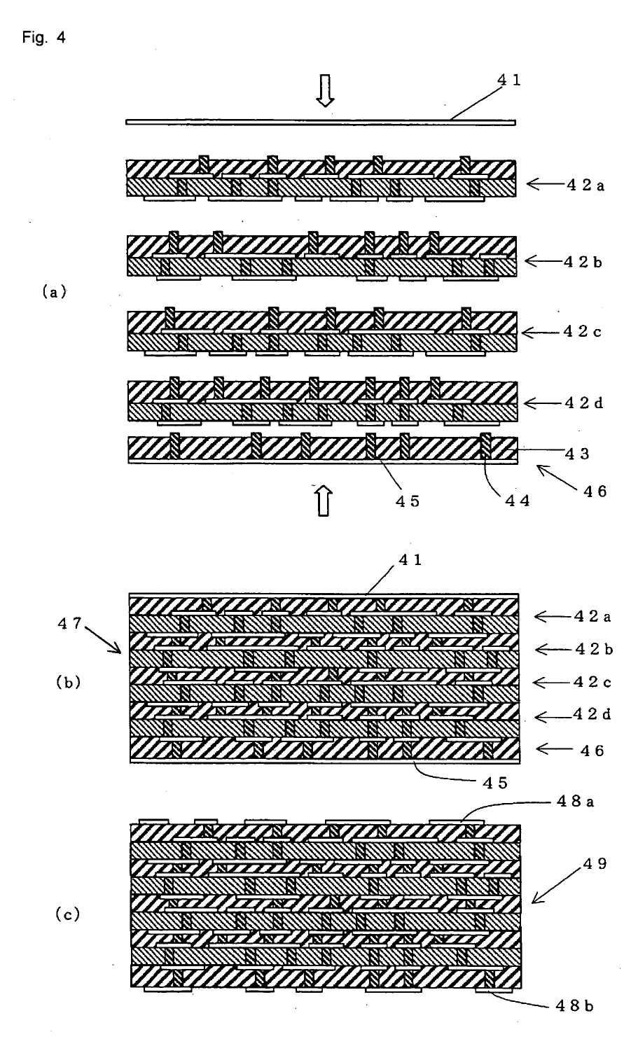

The multi-layered wiring board of the present invention and its production process of embodiment 4 are explained referring to FIG. 4. What is different in embodiment 4 from embodiment 3 is that one metal foil stuck connector 46 is used as one outermost member in addition to a plurality of the wiring substrate for intermediate connection.

As shown in FIG. 4(a), the plurality of the wiring substrates for intermediate connection 42a, 42b, 42c and 42d as used in the embodiment 3 each having the predetermined wiring layers are stacked onto a bottom side of a metal foil 41, and to a bottom side of the wiring substrate for intermediate connection 42d, the metal foil stuck connector 46 is stacked which comprises a prepreg sheet 43 (in an uncured condition or preferably in a semi-cured condition) having via hole conductors 44 (in an uncured condition or preferably in a semi-cured condition) and a metal foil (such as a copper foil) 45 on one whole surface of the prepreg sheet 43, followed by pressing them from their both sides while heating so as to completely cure the prepreg sheets of the wiring substrates for intermediate connection 42a, 42b, 42c and 42d and the via hole conductors and the prepreg sheet 43 of the metal stuck connector 46 and its via hole conductors 44, so that the laminate 47 as shown in FIG. 4(b) is formed.

Next, the multi-layered wiring board 49 is obtained by selectively etching the metal foils 41 and 45 as the outermost layers to form predetermined outermost wiring layers 48a and 48b.

As seen from the above, the present invention provides a process for the production of the multi-layered wiring board comprising the steps of:
stacking and aligning a plurality of the wiring substrates for intermediate connection 42a to 42d each having the predetermined wiring layers and an outermost wiring substrate as the metal foil stuck connector which comprises the prepreg sheet 43 having a metal foil 45 stuck onto its one side as well as the via hole conductor(s) at a predetermined position(s) such that the prepreg sheet and said wiring board are arranged alternately;
placing a metal foil 41 on the prepreg sheet of the top wiring substrate for intermediate connection of thus stacked wiring substrates for intermediate connection, followed by aligning all of them;
heating and pressing thus stacked wiring substrates for intermediate connection, the metal foil stuck prepreg sheet and the metal foil so as to laminate them together; and
selectively etching the metal foils 41 and 45 to form the predetermined-wiring layers 48a and 48b.

Embodiment 5

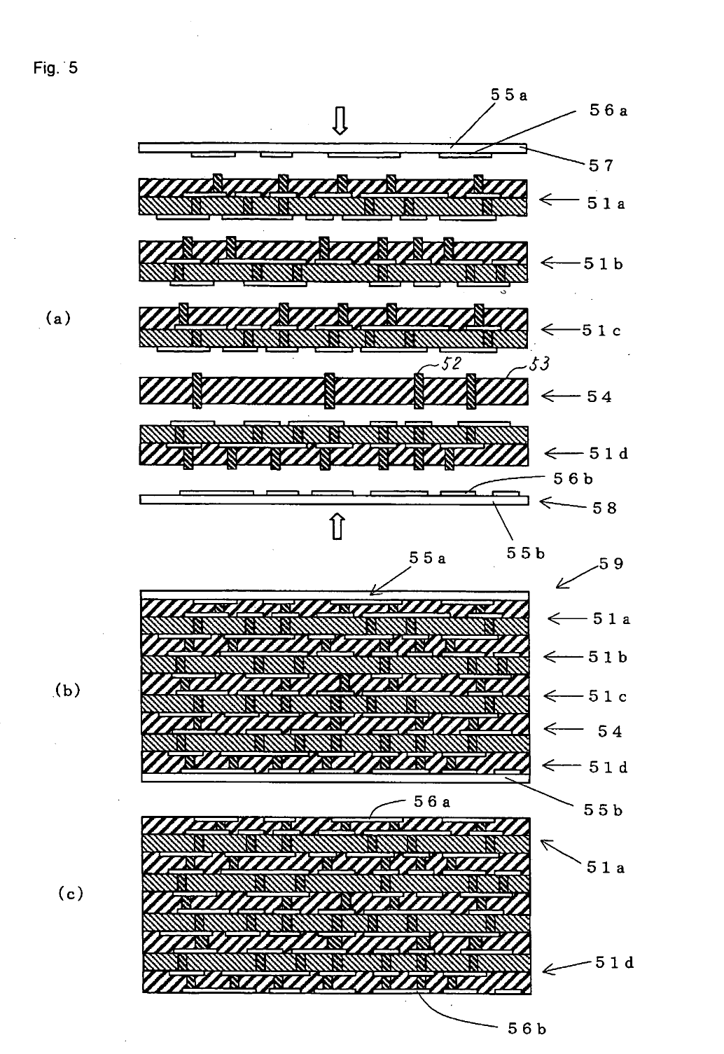

The multi-layered wiring board of the present invention and its production process of embodiment 5 are explained referring to FIG. 5. In this embodiment, the outermost wiring layer of the multi-layered wiring board is flush with a surface of the insulation layer (that is, the outermost surface of the multi-layered wiring board is substantially smooth and flat and no wiring surface protrudes from the insulation layer surface). As shown in FIGS. 5(a) to 5(c), a wiring layer transfer sheet is used for the formation of the outermost wiring layer in the production of the multi-layered wiring board.

First, the wiring substrates for intermediate connection of the present invention 51a, 51b and 51c are stacked and aligned in sequence as shown in FIG. 5(a). Then, the wiring substrate for intermediate connection 51d which is to be located at the bottom is arranged while its top-and-bottom orientation is opposite to the orientations of the other wiring substrates for intermediate connection, and an intermediate connector 54 that it is formed of a prepreg sheet 53 having via hole conductors 52 is stacked while being inserted between and aligned with the wiring substrates for intermediate connection 51c and 51d. Then, onto outermost sides of thus stacked and aligned wiring substrates for intermediate connection, an upper first wiring layer transfer sheet 57 comprising a carrier 55a on which a first outermost wiring layer 56a is formed and a lower wiring layer transfer sheet 58 comprising a carrier 55b on which a second outermost wiring layer 56b is formed are stacked and aligned respectively, followed by heating and pressing them together in the directions as shown with the arrows, whereby the via hole conductors and the prepreg sheets of the wiring substrates for intermediate connection and the intermediate connector are completely cured so that a laminate 59 shown in FIG. 5(b) is obtained.

Then, the carriers 55a and 55b are removed from the laminate 59, so that the multi-layered wiring board is obtained in which the first outermost wiring layer 56a and the second outermost wiring layer 56b are buried in the insulation layer surfaces of the wiring substrates for intermediate connection 51a and 51d so as to provide smooth surfaces as shown in FIG. 5(c).

As seen from the above, the present invention provides a process for the production of the multi-layered wiring board comprising the steps of:
stacking and aligning one or more first wiring substrates for intermediate connection 51a to 51c of the present invention, one or more second wiring substrates for intermediate connection 51d of the present invention of which top-and-bottom orientations are opposite to those of the former substrates and an intermediate connector 54 comprising a prepreg sheet having a via hole conductor(s) arranged between the first wiring substgrate(s) and the second wiring substrate(s) such that the prepreg sheet and the wiring board are arranged alternately;
placing and aligning a wiring-layer transfer sheet 57 or 58 (which comprises a predetermined wiring member 56a or 56b on a carrier 55a or 55b) as an outermost member on each outermost surface of thus stacked wiring substrates for intermediate connection and the intermediate connector;
heating and pressing thus stacked wiring substrates for intermediate connection, the intermediate connector, and the wiring layer transfer sheets so as to laminate them together to obtain a laminate; and
peeling off the carriers 55a and 55b from the laminate so that the wiring layers 56a and 56b are buried in the insulation layer surfaces which are formed from the prepreg sheets of the wiring substrates for intermediate connection.

Embodiment 6

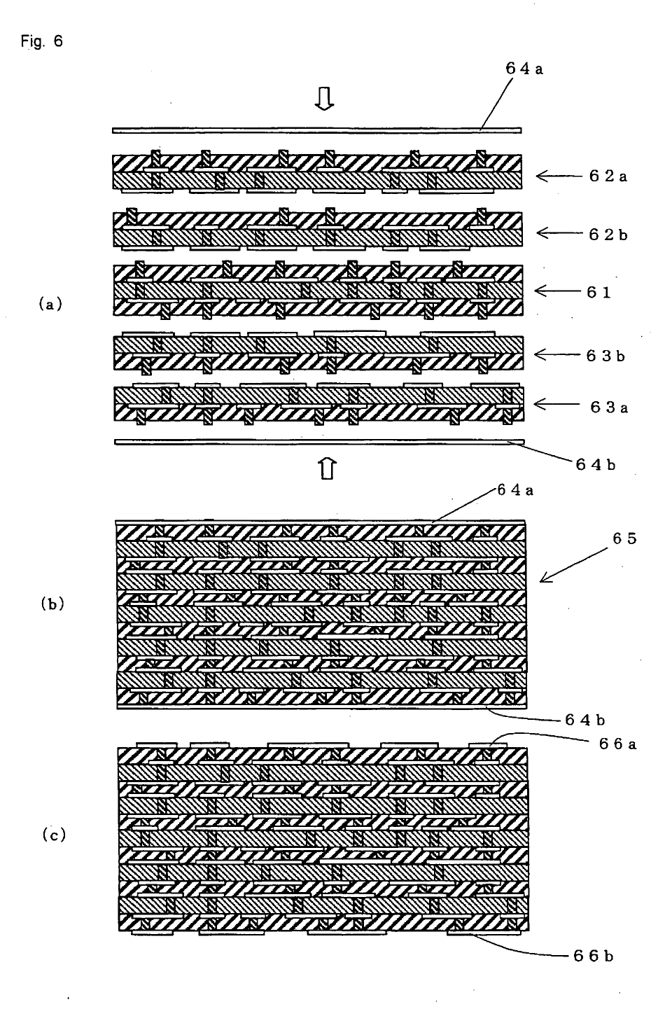

FIGS. 6(a) to 6(c) each shows a step of the production process of a multi-layered wiring board of embodiment 6 according to the present invention, and the shown embodiment uses the combination of the wiring substrates for intermediate connection as shown in FIGS. 1(a) and 1(b) together, that is, the wiring substrate for intermediate connection comprising the prepreg sheet on one surface of the double-sided layer wiring board and the wiring substrate for intermediate connection comprising the prepreg sheets on both surfaces of the double-sided layer wiring board.

At first, the wiring substrates for intermediate connection 62a and 62b each having the prepreg sheet on one surface thereof are placed on one side of the wiring substrate for intermediate connection 61 having the prepreg sheets on its both sides, and the wiring substrates for intermediate connection 63a and 63b of which top-and-bottom orientations are opposite to those of the substrates 62a and 62b are placed on the other side of the wiring substrate for intermediate connection 61 followed by being aligned as shown in FIG. 6(a), and metal foils 64a and 64b as the outermost members are further stacked on and aligned with the outermost wiring substrates for intermediate connection, followed by heating and pressing them as shown with the arrows so as to completely cure the prepreg sheets and the via hole conductors which form the wiring substrates for intermediate connection, so that the laminate as shown in FIG. 6(b) is obtained.

Next, the metal foils 64a and 64b on the both sides of the laminate 65 are selectively etched by the conventional photolithography method to form the predetermined outermost wiring layers 66a and 66b, so that the multi-layered wiring board as shown in FIG. 6(c) is obtained.

It is noted that the shown embodiment 6 has been explained with reference to the example wherein each of two wiring substrates for intermediate connection 62 or 63 each having the prepreg sheets on its one side are placed on each side of the wiring substrate for intermediate connection 61 having the prepreg sheets on their both sides, but the number of the wiring substrate for intermediate connection 62 or 63 arranged may be one or greater than two, and the wiring substrates for intermediate connection 62 or 63 may be arranged on only one side of the wiring substrate for intermediate connection 61 having the prepreg sheets on its both sides.

As seen from the above, the present invention provides a process for the production of the multi-layered wiring board comprising the steps of:
stacking and aligning one or more wiring substrates for intermediate connection 62a and 62b as well as 63a and 63b each having predetermined wiring layers on each side of the wiring substrates for intermediate connection 66 having the prepreg sheet on its each side such that each of said wiring boards is located inside;
placing metal foils 64a and 64b on outermost surfaces of thus stacked wiring substrates for intermediate connection respectively;
heating and pressing the wiring substrates for intermediate connection 62 and 63 and the metal foils 64a and 64b so as to laminate them together to obtain a laminate; and
selectively etching the metal foils so as to form predetermined wiring layers.

Embodiment 7

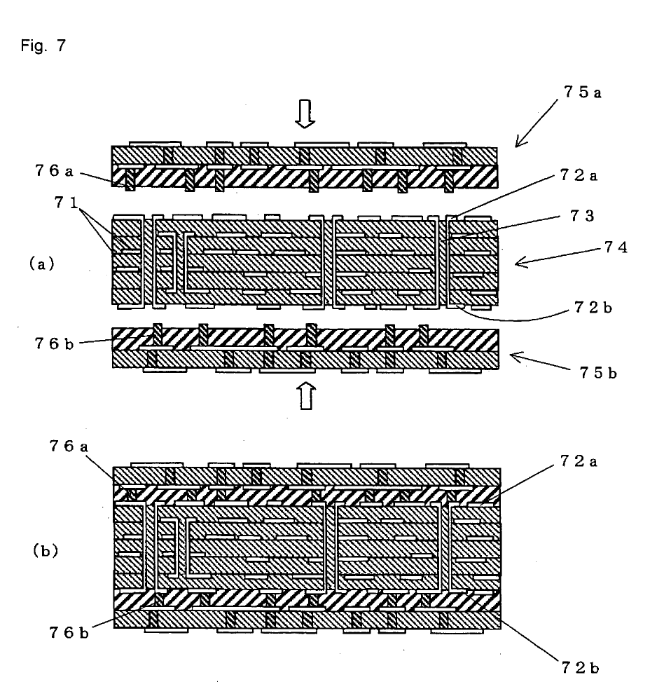

The production process of a multi-layered wiring board of embodiment 7 of the present invention is explained referring to FIG. 7.

In the above embodiments 3 to 6, the multi-layered wiring board is formed by collectively heating and pressing a plurality of the wiring substrates for intermediate connection of the present invention so as to laminate them together. In the present embodiment, a double-sided or multi-layered wiring board which comprises for example a glass/epoxy resin substrate is used as a core member, on both sides of which the wiring substrates for intermediate connection of the present invention are arranged respectively to form the multi-layered wiring board.

As shown in FIG. 7(a), on either side of a core wiring board 74 comprising the glass/epoxy resin substrate as an insulation layer wherein a plurality of inside wiring layers 71 are formed, and the outermost wiring layers 72a and 72b and a portion of the inside wiring layers 71 are electrically connected through plated via hole conductors 73, the wiring substrate for intermediate connection 75a as shown in FIG. 1(a) and the wiring substrate for intermediate connection 75b which corresponds to the wiring substrate for intermediate connection 75a of which top-and-bottom orientation is reversed are placed respectively and aligned, followed by collectively heating and pressing them as shown with the arrows to laminate them together, so that the via hole conductors 76a and 76b of formed in the wiring substrates for intermediate connection 75a and 75b are compressed and are strongly connected to the outermost wiring layers 72a and 72b respectively so that the multi-layered wiring board as shown in FIG. 7(b) is obtained.

It is noted that as the core wiring board 74, the multi-layered wiring board according to the present invention as shown in FIGS. 3 to 6 may be used or a conventional multi-layered glass/epoxy resin wiring board produced by the buildup method. FIG. 7 shows an example wherein one wiring substrate for intermediate connection 75a or 75b is disposed on either side of the core wiring board 74, but it is possible to use a plurality of the wiring substrates for intermediate connection as shown in FIGS. 1(a) or 1(b) are used alone or in combination.

As seen from the above, the present invention provides a process for the production of the multi-layered wiring board comprising the steps of:
stacking and aligning on at least one side of a double-sided wiring board or multi-layered wiring board as a core wiring board 74, one or more wiring substrates for intermediate connection 75a and 75b each having predetermined wiring layers such that the prepreg sheets of the wiring substrates for intermediate connection are located inside; and
heating and pressing thus stacked wiring substrates for intermediate connection and the core wiring board 74 so as to laminate them together.

It is noted that the wiring substrates for intermediate connection according to the present invention may be placed on only one side of the core wiring board 74.

Embodiment 8

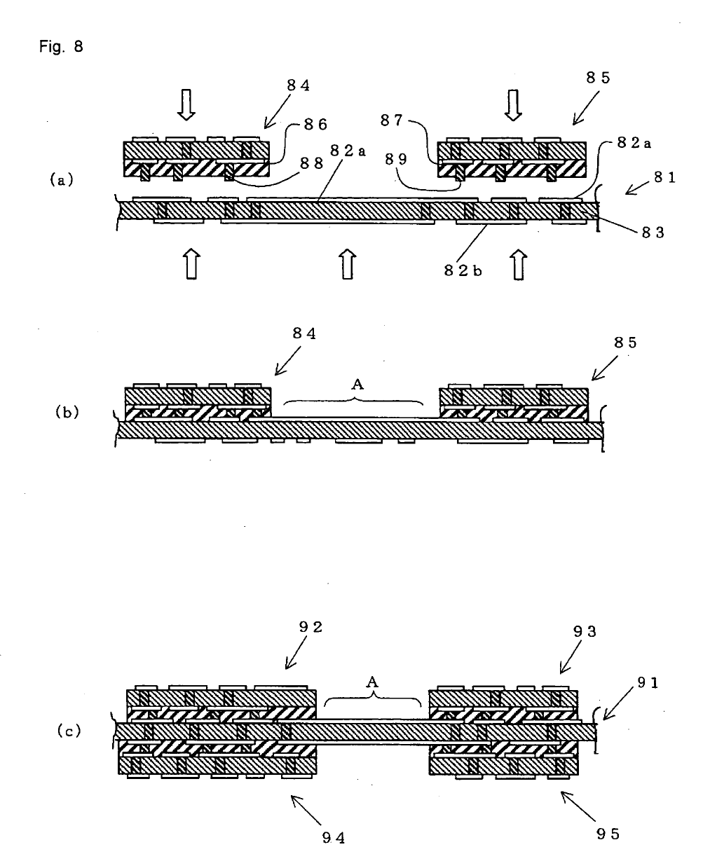

A multi-layered wiring board of embodiment 8 of the present invention and its production process are explained referring to FIG. 8. FIGS. 8(a) to 8(c) each schematically shows a step of the process in a cross-sectional view.

What is different in the multi-layered wiring board of the embodiment 8 from the multi-layered wiring board of the embodiment 7 resides in that the wiring substrate for intermediate connection 84 or 85 is placed on a core wiring board 81 to form the multi-layered wiring board and an occupying area when mounted of the wiring substrate for intermediate connection 84 or 85 is smaller than an area of the surface of the core wiring board 81 on which the wiring substrate for intermediate connection is mounted, as seen from FIG. 8.

As shown in FIG. 8(a), a double-sided wiring board or multi-layered wiring board 81 is used as a core wiring board which comprises., as an insulation layer 83, a synthetic resin film having flexibility such as a polyimide film on each side of which a wiring layer 82b or 82b is formed is used in this embodiment, and predetermined wiring substrates for intermediate connection 84 and 8.5 which are similar to those as explained in the above embodiments are placed on the predetermined areas of the core wiring board 81, followed by heating and pressing them as shown with the arrows so as to connect the outermost wiring layers 82a to the wiring layers 86 and 87 of the wiring substrates for intermediate connection 84 and 85 through the via hole conductors 88 and 89 respectively. As a result, a multi-layered wiring board as shown in FIG. 8(b) which comprises the core wiring board 81 as a mother board and the two wiring substrates for intermediate connection 84 and 85 as carrier boards mounted on the mother board.

It is noted that the core wiring board has one each (i.e. totally two) of the wiring substrates for intermediate connection 84 and 85 on its one side in FIGS. 8(a) and 8(b), but the number of the wiring substrate for intermediate connection may be one or may be more than two as required. Further, the core wiring board 91 may have the wiring substrate(s) for intermediate connection 92 to 95 on both sides thereof as shown in 8(c).

In FIG. 8, as the wiring substrate for intermediate connection 84 or 85, one substrate shown in FIG. 1(a) stacked on the core wiring board 81 is shown for to simplicity of the drawings, but it is possible to laminate a plurality of the wiring substrates for intermediate connection of the present invention on the core wiring board 81. In other embodiment, the core wiring board 81 may be a multi-layered wiring board.

Further, in the multi-layered wiring board according to the present embodiment, an area “A” of the core wiring substrate 81 of FIG. 8(b) or 8(c) where no wiring substrate for intermediate connection is placed may be used for a land area on which other electronic part such as a semiconductor element is mounted. In addition, since the area “A” is thinner compared with the other area so that is bendable, the multi-layered wiring board may be contained while being folded in a limited narrow space effectively of a compact and thin electronic device such as a mobile phone. Therefore, such multi-layered wiring board is effective for the improvement in high density mounting.

In this embodiment, when the core wiring board is a heat resistive and flexible wiring board, its insulation layer and an intermediate connector optionally present may comprise a synthetic resin film made of a p-aramid, a poly-p-phenylene benzobisoxazole, an all aromatic polyester, a polyetherimide, a polyetherketone, a polyetheretherketone, a polyethylene terephthalate, a polytetrafluoroethylene, a polyethersulphon, a polyester terephthalate or a polyphenylene sulfide in addition to the polyimide as described above.

The wiring substrate for intermediate connection of the present invention is superior to handling it in the lamination step, which leads to extremely high accuracy of positioning, so that super multi-layered wiring board comprising fine wiring layers (of which layer number is usually not smaller than ten) can be produced.

It is noted that the present invention covers the following modes:

Mode 1

A wiring substrate for intermediate connection comprising:
(1) a wiring board having a plurality of wiring layers which are connected through a via hole conductor(s) with each other; and
(2) a prepreg sheet having a via hole conductor(s) at a predetermined position(s) which sheet is disposed on at least one side of the wiring board.

Mode 2

The wiring substrate for intermediate connection of mode 1 wherein said wiring board is a double-sided wiring board comprising the wiring layers on its both sides.

Mode 3

The wiring substrate for intermediate connection of mode 1 wherein said wiring board is a multi-layered wiring board which comprises the wiring layers on its both sides and also inside.

Mode 4

The wiring substrate for intermediate connection of any one of modes 1 to 3 wherein each of said wiring board and the prepreg sheet has a thickness of not greater than 50 μm.

Mode 5

The wiring substrate for intermediate connection of any one of modes 1 to 4 wherein a maximum diameter of the via hole conductor is not larger than 100 μm.

Mode 6

The wiring substrate for intermediate connection of any one of modes 1 to 5 wherein at least one of said wiring board and the prepreg sheet is formed from an unwoven fabric material which is impregnated with a thermoset resin.

Mode 7

The wiring substrate for intermediate connection of mode 6 wherein the unwoven fabric material comprises a fiber which is made of at least one selected from the group consisting of an organic material such as a p-aramid, a polyimide, a poly-p-phenylene benzobisoxazole, an all aromatic polyester, a PTFE, a polyethersulfone and a polyetherimide and an inorganic material such as a glass and alumina.

Mode 8

The wiring substrate for intermediate connection of any one of modes 1 to 5 wherein at least one of said wiring board and the prepreg sheet is formed from a woven fabric material which is impregnated with a thermoset resin.

Mode 9

The wiring substrate for intermediate connection of mode 8 wherein the woven fabric material comprises a fiber which is made of at least one selected from the group consisting of an organic material such as an aramid and an all aromatic polyester and an inorganic material such as a glass and alumina.

Mode 10

The wiring substrate for intermediate connection of any one of modes 1 to 9 wherein the prepreg sheet comprises a synthetic resin film made of at least one selected from the group consisting of a p-aramid, a poly-p-phenylene benzobisoxazole, an all aromatic polyester, a polyetherimide, a polyetherketone, a polyetheretherketone, a polyethylene terephthalate, a polytetrafluoroethylene, a polyethersulfone, a polyester terephthalate, a polyimide and a polyphenylene sulfide, and an epoxy resin is applied in its prepreg condition to one surface or both surfaces of the film as an adhesive.

Mode 11

The wiring substrate for intermediate connection of any one of modes 1 to 10 wherein the via hole conductor comprises powder of at least one metal selected from the group consisting of gold, silver, copper, palladium, tin and nickel and a thermoset resin as a binder component.

Mode 12

A production process of a wiring substrate for intermediate connection which comprises:
(1) a wiring board having a plurality of wiring layers which are connected through a via hole conductor(s) with each other; and
(2) a prepreg sheet having a via hole conductor(s) at a predetermined position(s) which sheet is disposed on at least one side of the wiring board;
the process comprising the steps of:
(a) stacking the prepreg sheet having a release film thereon on at least one side of said wiring board so as to laminate them together;
(b) forming a completely through hole(s) or a not completely through hole(s) from the release film side of the prepreg sheet;
(c) filling the hole(s) with an electrically conductive paste so as to form the via hole conductor(s); and
(d) optionally, removing the release film.

Mode 13

The production process of mode 12 wherein at least one of said wiring board and the prepreg sheet is formed from an unwoven fabric material which is impregnated with a thermoset resin.

Mode 14

The production process of mode 13 wherein the unwoven fabric material comprises a fiber which is made of at least one selected from the group consisting of an organic material such as a p-aramid, a polyimide, a poly-p-phenylene benzobisoxazole, an all aromatic polyester, a PTFE, a polyethersulfone and a polyetherimide and an inorganic material such as a glass and alumina.

Mode 15

The production process of mode 12 wherein at least one of said wiring board and the prepreg sheet is formed from a woven fabric material which is impregnated with a thermoset resin.

Mode 16

The production process of mode 15 wherein the woven fabric material comprises a fiber which is made of at least one selected from the group consisting of an organic material such as an aramid and an all aromatic polyester and an inorganic material such as a glass and alumina.

Mode 17

The production process of any one of modes 12 to 16 wherein the prepreg sheet comprises a synthetic resin film made of at least one selected from the group consisting of a p-aramid, a poly-p-phenylene benzobisoxazole, an all aromatic polyester, a polyetherimide, a polyetherketone, a polyetheretherketone, a polyethylene terephthalate, a polytetrafluoroethylene, a polyethersulfone, a polyester terephthalate, a polyimide and a polyphenylene sulfide, and an epoxy resin is applied in its prepreg condition to one surface or both surfaces of the film as an adhesive.

Mode 18

The production process of mode 17 wherein the thermoset resin as the adhesive is at least one selected from the group consisting of an epoxy resin, a phenol resin and a cyanate resin.

Mode 19

The production process of any one of modes 12 to 18 wherein the via hole conductor comprises powder of at least one metal selected from the group consisting of gold, silver, copper, palladium, tin and nickel and a thermoset resin as a binder component.

Mode 20

The production process of any one of modes 12 to 19 wherein the prepreg sheet is at least one of a woven fabric sheet and an unwoven fabric sheet which comprises at least one of a thermoplastic resin and a thermoset resin which includes an uncured component.

Mode 21

The production process of any one of modes 13 to 20 wherein the thermoset resin of the prepreg sheet is at least one selected from the group consisting of an epoxy resin, a phenol resin and a cyanate resin.

Mode 22

The production process of any one of modes 12 to 21 wherein the release film is made of at least one selected from the group consisting of a polyethylene terephthalate, a polyester terephthalate, a polyimide, a polyphenylene sulfide, a polypropylene and a polyphenylene oxide.

Mode 23

A multi-layered wiring board which is formed by laminating together a plurality of the wiring substrates for intermediate connection of any one of modes 1 to 11 each having predetermined wiring layers.

Mode 24

The multi-layered wiring board of mode 23 which is formed by laminating together in addition to the plural wiring substrates for intermediate connection of any one of modes 1 to 11, one or more other wiring board(s) and/or connector(s).

Mode 25

A process for the production of a multi-layered wiring board comprising laminating together a plurality of the wiring substrates for intermediate connection of any one of modes 1 to 11 each having predetermined wiring layers.

Mode 26

The process for the production of the multi-layered wiring board of mode 25 comprising the steps of:
stacking and aligning a plurality of the wiring substrates for intermediate connection according to any one of modes 1 to 11 each having predetermined wiring layers such that the prepreg sheet and said wiring board are arranged alternately;
placing a metal foil on a top surface of the prepreg sheet of a top wiring substrate for intermediate connection of thus stacked wiring substrates for intermediate connection while aligning the foil with the stacked substrates;
heating and pressing the wiring substrates for intermediate connection and the metal foil together so as to laminate them integrally; and
selectively etching the metal foil to form the predetermined wiring layer.

Mode 27

The process for the production of the multi-layered wiring board of mode 25 comprising the steps of:
stacking and aligning a plurality of the wiring substrates for intermediate connection according to any one of modes 1 to 11 each having the predetermined wiring layers and an outermost wiring substrate as a metal foil stuck connector which comprises a prepreg sheet having a metal foil stuck on its one side as well as a via hole conductor(s) at a predetermined position(s) such that the prepreg sheet and said wiring board are arranged alternately;
placing a metal foil on the prepreg sheet of a top wiring substrate for intermediate connection of thus stacked wiring substrates for intermediate connection, followed by aligning all of them;
heating and pressing thus stacked wiring substrates for intermediate connection, the metal foil stuck prepreg sheet and the metal foil so as to laminate them together; and
selectively etching the metal foils to form predetermined wiring layers.

Mode 28

The process for the production of the multi-layered wiring board of mode 25 comprising the steps of:
stacking and aligning one or more first wiring substrates for intermediate connection according to any one of modes 1 to 11, one or more second wiring substrates for intermediate connection according to any one of modes 1 to 11 of which top-and-bottom orientations are opposite to those of the former substrates and an intermediate connector 54 comprising a prepreg sheet having a via hole conductor(s) arranged between the first wiring substgrate(s) and the second wiring substrate(s) such that the prepreg sheet and the wiring board are arranged alternately;
placing and aligning a wiring layer transfer sheet (which comprises a predetermined wiring layer on a carrier) as an outermost member on each outermost surface of thus stacked wiring substrates for intermediate connection and the intermediate connector;
heating and pressing thus stacked wiring substrates for intermediate connection, the intermediate connector, and the wiring layer transfer sheets so as to laminate them together and obtain a laminate; and
peeling off the carriers from the laminate so that the wiring layers of the transfer sheets are buried in the insulation layer surfaces which are formed from the prepreg sheets of the wiring substrates for intermediate connection.

Mode 29

The process for the production of the multi-layered wiring board of mode 25 comprising the steps of:
stacking and aligning one or more wiring substrates for intermediate connection according to any one of modes 1 to 11 each having predetermined wiring layers on both sides of wiring substrate for intermediate connection according to any one of modes 1 to 11 which has the prepreg sheet on its both sides such that each of said wiring boards of the wiring substrates for intermediate connection is located inside;
placing metal foils on outermost surfaces of thus stacked wiring substrates for intermediate connection respectively;
heating and pressing the wiring substrates for intermediate connection and the metal foils so as to laminate them together to obtain a laminate; and
selectively etching the metal foils so as to form predetermined wiring layers.

Mode 30

A multi-layered wiring board comprising a double-sided wiring board or a multi-layered wiring board as a core wiring board; and
one or plural wiring substrates for intermediate connection according to any one of modes 1 to 11 disposed on and laminated to one side or both sides of the core wiring board while aligned with the core wiring board.

Mode 31

The multi-layered wiring board of mode 30 wherein the wiring substrate for intermediate connection has a mounting area which is smaller than an area of a surface of the core wiring substrate on which surface the wiring substrate for intermediate connection is disposed.

Mode 32

The multi-layered wiring board of mode 30 or 31 wherein the core wiring board is a printed wiring board which comprises an insulation layer comprising a glass fiber fabric impregnated with a thermoset resin.

Mode 33

The multi-layered wiring board of mode 30 or 31 wherein the core wiring board is a printed wiring board which comprises as an insulation layer a synthetic resin film having flexibility.

Mode 34

The multi-layered wiring board of mode 33 wherein the synthetic resin film is made of at least one selected from the group consisting of a p-aramid, a poly-p-phenylene benzobisoxazole, an all aromatic polyester., a polyetherimide, a polyetherketone, a polyetheretherketone, a polyethylene terephthalate, a polytetrafluoroethylene, a polyethersulfone, a polyester terephthalate, a polyimide and a polyphenylene sulfide,

Mode 35

The multi-layered wiring board of any one of modes 30 to 34 wherein the core wiring board comprises as its outermost layer a wiring layer which is formed by the buildup method.

Mode 36

A process for the production of a multi-layered wiring board comprising the steps of:
stacking and aligning on at least one side of a double-sided wiring board or multi-layered wiring board as a core wiring board, one or more wiring substrates for intermediate connection according to any one of modes 1 to 11 each having predetermined wiring layers such that the prepreg sheets of the wiring substrates for intermediate connection are located inside; and
heating and pressing thus stacked wiring substrates for intermediate connection and the core wiring board so as to laminate them together, so that an outermost wiring layer of the core wiring board is connected to the wiring layer of the wiring substrate for intermediate connection which is adjacent to the core wiring board and also the wiring layers of the wiring substrates for intermediate connection are connected as predetermined.

Mode 37

The production process of mode 36 wherein the wiring substrate for intermediate connection which is adjacent to the core wiring board has a mounting area which is smaller than an area of a surface of the core wiring substrate on which surface the wiring substrate for intermediate connection is disposed.

Mode 38

The wiring substrate for intermediate connection of any one of modes 1 to 11 wherein the prepreg sheet comprises a release film which forms an outermost layer of the wiring substrate for intermediate connection.

1. A wiring substrate for intermediate connection comprising:
(1) a wiring board having a plurality of wiring layers which are connected through a via hole conductor(s) with each other; and
(2) a prepreg sheet having a via hole conductor(s) at a predetermined position(s) which sheet is disposed on at least one side of the wiring board.

2. The wiring substrate for intermediate connection according to claim 1 wherein said wiring board is a double-sided wiring board comprising the wiring layers on its both sides.

3. The wiring substrate for intermediate connection according to claim 1 wherein said wiring board is a multi-layered wiring board which comprises the wiring layers on its both sides and also inside.

4. The wiring substrate for intermediate connection according to claim 1 wherein each of said wiring board and the prepreg sheet has a thickness of not greater than 50 μm.

5. The wiring substrate for intermediate connection according to claim 1 wherein a maximum diameter of the via hole conductor is not larger than 100 μm.

6. The wiring substrate for intermediate connection according to claim 1 wherein at least one of said wiring board and the prepreg sheet is formed from an unwoven fabric material which is impregnated with a thermoset resin.

7. The wiring substrate for intermediate connection according to claim 6 wherein the unwoven fabric material comprises a fiber which is made of at least one selected from the group consisting of an organic material such as a p-aramid, a polyimide, a poly-p-phenylene benzobisoxazole, an all aromatic polyester, a PTFE, a polyethersulfone and a polyetherimide and an inorganic material such as a glass and alumina.

8. The wiring substrate for intermediate connection according to claim 1 wherein at least one of said wiring board and the prepreg sheet is formed from a woven fabric material which is impregnated with a thermoset resin.

9. The wiring substrate for intermediate connection according to claim 8 wherein the woven fabric material comprises a fiber which is made of at least one selected from the group consisting of an organic material such as an aramid and an all aromatic polyester and an inorganic material such as a glass and alumina.

10. The wiring substrate for intermediate connection according to claim 1 wherein the prepreg sheet comprises a synthetic resin film made of at least one selected from the group consisting of a p-aramid, a poly-p-phenylene benzobisoxazole, an all aromatic polyester, a polyetherimide, a polyetherketone, a polyetheretherketone, a polyethylene terephthalate, a polytetrafluoroethylene, a polyethersulfone, a polyester terephthalate, a polyimide and a polyphenylene sulfide, and an epoxy resin is applied in its prepreg condition to one surface or both surfaces of the film as an adhesive.

11. The wiring substrate for intermediate connection according to claim 1 wherein the via hole conductor comprises powder of at least one metal selected from the group consisting of gold, silver, copper, palladium, tin and nickel and a thermoset resin as a binder component.

12. A production process of a wiring substrate for intermediate connection which comprises:
(1) a wiring board having a plurality of wiring layers which are connected through a via hole conductor(s) with each other; and
(2) a prepreg sheet having a via hole conductor(s) at a predetermined position(s) which sheet is disposed on at least one side of the wiring board;
the process comprising the steps of:
(a) stacking the prepreg sheet having a release film thereon on at least one side of said wiring board so as to laminate them together;
(b) forming a completely through hole(s) or a not completely through hole(s) from the release film side of the prepreg sheet;
(c) filling the hole(s) with an electrically conductive paste so as to form the via hole conductor(s); and
(d) optionally, removing the release film.

13. The production process according to claim 12 wherein at least one of said wiring board and the prepreg sheet is formed from an unwoven fabric material which is impregnated with a thermoset resin.

14. The production process according to claim 13 wherein the unwoven fabric material comprises a fiber which is made of at least one selected from the group consisting of an organic material such as a p-aramid, a polyimide, a poly-p-phenylene benzobisoxazole, an all aromatic polyester, a PTFE, a polyethersulfone and a polyetherimide and an inorganic material such as a glass and alumina.

15. The production process according to claim 12 wherein at least one of said wiring board and the prepreg sheet is formed from a woven fabric material which is impregnated with a thermoset resin.

16. The production process according to claim 15 wherein the woven fabric material comprises a fiber which is made of at least one selected from the group consisting of an organic material such as an aramid and an all aromatic polyester and an inorganic material such as a glass and alumina.

17. The production process according to claim 12 wherein the prepreg sheet comprises a synthetic resin film made of at least one selected from the group consisting of a p-aramid, a poly-p-phenylene benzobisoxazole, an all aromatic polyester, a polyetherimide, a polyetherketone, a polyetheretherketone, a polyethylene terephthalate, a polytetrafluoroethylene, a polyethersulfone, a polyester terephthalate, a polyimide and a polyphenylene sulfide, and an epoxy resin is applied in its prepreg condition to one surface or both surfaces of the film as an adhesive.

18. The production process according to claim 17 wherein the thermoset resin as the adhesive is at least one selected from the group consisting of an epoxy resin, a phenol resin and a cyanate resin.

19. The production process according to claim 12 wherein the via hole conductor comprises powder of at least one metal selected from the group consisting of gold, silver, copper, palladium, tin and nickel and a thermoset resin as a binder component.

20. The production process according to claim 12 wherein the prepreg sheet is at least one of a woven fabric sheet and an unwoven fabric sheet which comprises at least one of a thermoplastic resin and a thermoset resin which includes an uncured component.

21. The production process according to claim 13 wherein the thermoset resin of the prepreg sheet is at least one selected from the group consisting of an epoxy resin, a phenol resin and a cyanate resin.

22. The production process according to claim 12 wherein the release film is made of at least one selected from the group consisting of a polyethylene terephthalate, a polyester terephthalate, a polyimide, a polyphenylene sulfide, a polypropylene and a polyphenylene oxide.

23. A multi-layered wiring board which is formed by laminating together a plurality of the wiring substrates for intermediate connection according to claim 1 each having predetermined wiring layers.

24. The multi-layered wiring board according to claim 23 which is formed by laminating together in addition to the plural wiring substrates for intermediate connection, one or more other wiring board(s) and/or connector(s).

25. A process for the production of a multi-layered wiring board comprising laminating together a plurality of the wiring substrates for intermediate connection according to claim 1 each having predetermined wiring layers.

26. The process for the production of the multi-layered wiring board according to claim 25 comprising the steps of:
stacking and aligning a plurality of the wiring substrates for intermediate connections each having predetermined wiring layers such that the prepreg sheet and said wiring board are arranged alternately;
placing a metal foil on a top surface of the prepreg sheet of a top wiring substrate for intermediate connection of thus stacked wiring substrates for intermediate connection while aligning the foil with the stacked substrates;
heating and pressing the wiring substrates for intermediate connection and the metal foil together so as to laminate them integrally; and
selectively etching the metal foil to form the predetermined wiring layer.

27. The process for the production of the multi-layered wiring board according to claim 25 comprising the steps of:
stacking and aligning a plurality of the wiring substrates for intermediate connections each having the predetermined wiring layers and an outermost wiring substrate as a metal foil stuck connector which comprises a prepreg sheet having a metal foil stuck on its one side as well as a via hole conductor(s) at a predetermined position(s) such that the prepreg sheet and said wiring board are arranged alternately;
placing a metal foil on the prepreg sheet of a top wiring substrate for intermediate connection of thus stacked wiring substrates for intermediate connection, followed by aligning all of them;
heating and pressing thus stacked wiring substrates for intermediate connection, the metal foil stuck prepreg sheet and the metal foil so as to laminate them together; and
selectively etching the metal foils to form predetermined wiring layers.

28. The process for the production of the multi-layered wiring board according to claim 25 comprising the steps of:
stacking and aligning one or more first wiring substrates for intermediate connection, one or more second wiring substrates for intermediate connection of which top-and-bottom orientations are opposite to those of the former substrates and an intermediate connector 54 comprising a prepreg sheet having a via hole conductor(s) arranged between the first wiring substgrate(s) and the second wiring substrate(s) such that the prepreg sheet and the wiring board are arranged alternately;
placing and aligning a wiring layer transfer sheet (which comprises a predetermined wiring layer on a carrier) as an outermost member on each outermost surface of thus stacked wiring substrates for intermediate connection and the intermediate connector;
heating and pressing thus stacked wiring substrates for intermediate connection, the intermediate connector, and the wiring layer transfer sheets so as to laminate them together and obtain a laminate; and
peeling off the carriers from the laminate so that the wiring layers of the transfer sheets are buried in the insulation layer surfaces which are formed from the prepreg sheets of the wiring substrates for intermediate connection.

29. The process for the production of the multi-layered wiring board according to claim 25 comprising the steps of:
stacking and aligning one or more wiring substrates for intermediate connections each having predetermined wiring layers on both sides of wiring substrate for intermediate connection which has the prepreg sheet on its both sides such that each of said wiring boards of the wiring substrates for intermediate connection is located inside;
placing metal foils on outermost surfaces of thus stacked wiring substrates for intermediate connection respectively;
heating and pressing the wiring substrates for intermediate connection and the metal foils so as to laminate them together to obtain a laminate; and
selectively etching the metal foils so as to form predetermined wiring layers.

30. A multi-layered wiring board comprising
a double-sided wiring board or a multi-layered wiring board as a core wiring board; and
one or plural wiring substrates for intermediate connection according to claim 1 disposed on and laminated to one side or both sides of the core wiring board while aligned with the core wiring board.

31. The multi-layered wiring board according to claim 30 wherein the wiring substrate for intermediate connection has a mounting area which is smaller than an area of a surface of the core wiring substrate on which surface the wiring substrate for intermediate connection is disposed.

32. The multi-layered wiring board according to claim 30 wherein the core wiring board is a printed wiring board which comprises an insulation layer comprising a glass fiber fabric impregnated with a thermoset resin.

33. The multi-layered wiring board according to claim 30 wherein the core wiring board is a printed wiring board which comprises as an insulation layer a synthetic resin film having flexibility.

34. The multi-layered wiring board according to claim 33 wherein the synthetic resin film is made of at least one selected from the group consisting of a p-aramid, a poly-p-phenylene benzobisoxazole, an all aromatic polyester, a polyetherimide, a polyetherketone, a polyetheretherketone, a polyethylene terephthalate, a polytetrafluoroethylene, a polyethersulfone, a polyester terephthalate, a polyimide and a polyphenylene sulfide,

35. The multi-layered wiring board according to claim 30 wherein the core wiring board comprises as its outermost layer a wiring layer which is formed by the buildup method.

36. A process for the production of a multi-layered wiring board comprising the steps of:
stacking and aligning on at least one side of a double-sided wiring board or multi-layered wiring board as a core wiring board, one or more wiring substrates for intermediate connection according to claim 1 each having predetermined wiring layers such that the prepreg sheets of the wiring substrates for intermediate connection are located inside; and
heating and pressing thus stacked wiring substrates for intermediate connection and the core wiring board so as to laminate them together, so that an outermost wiring layer of the core wiring board is connected to the wiring layer of the wiring substrate for intermediate connection which is adjacent to the core wiring board and also the wiring layers of the wiring substrates for intermediate connection are connected as predetermined.

37. The production process according to claim 36 wherein the wiring substrate for intermediate connection which is adjacent to the core wiring board has a mounting area which is smaller than an area of a surface of the core wiring substrate on which surface the wiring substrate for intermediate connection is disposed.

38. The wiring substrate for intermediate connection according to claim 1 wherein the prepreg sheet comprises a release film which forms an outermost layer of the wiring substrate for intermediate connection.
